(19) United States
(12) Patent Application Publication
(10) Pub. No.: US 2025/0370068 A1
(43) Pub. Date: Dec. 4, 2025

(54) METHOD FOR TRAINING TRANSFORMER FAULT DETECTION MODEL, FAULT DIAGNOSIS METHOD, AND RELATED DEVICE

(71) Applicant: STATE GRID INFORMATION & TELECOMMUNICATION GROUP CO., LTD., Beijing (CN)

(72) Inventors: Xiaoning Li, Beijing (CN); Jingpo Bai, Beijing (CN); Zhen Qiu, Beijing (CN); Yuanyuan Liu, Beijing (CN); Yiping Zhou, Beijing (CN); Min Jin, Beijing (CN); Xingtao Wang, Beijing (CN); Dawei Lu, Beijing (CN); Xiaoguang Huang, Beijing (CN); Yong Su, Beijing (CN); Wenpu Li, Beijing (CN); Ting Guo, Beijing (CN)

(21) Appl. No.: 19/300,720

(22) Filed: Aug. 15, 2025

Related U.S. Application Data
(63) Continuation-in-part of application No. PCT/CN2024/141305, filed on Dec. 23, 2024.

(30) Foreign Application Priority Data
Nov. 23, 2023 (CN) 202311574422.5

(51) Int. Cl. G01R 31/62; G06N 3/084

(52) U.S. Cl. CPC G01R 31/62; G06N 3/084

(57) ABSTRACT

Provided are a method for training a transformer fault detection model, a fault diagnosis method, and a related device. The method includes: obtaining an initial voiceprint signal of a transformer and a fault type corresponding to the initial voiceprint signal; preprocessing the initial voiceprint signal to obtain an input signal, and establishing an input signal dataset; performing feature extraction on a first input signal in the training dataset based on a preset feature extraction algorithm to obtain a first voiceprint feature; training an initial detection model based on the first voiceprint feature and a first fault type corresponding to the first input signal to obtain a first training result; determining a loss function based on the first training result and the first fault type; and iteratively adjusting a weight value of the initial detection model until the loss function converges to obtain a fault detection model.

### CROSS REFERENCE TO RELATED APPLICATIONS

The present application is a Continuation-In-Part Application of PCT Application No. PCT/CN2024/141305 filed on Dec. 23, 2024, which claims the benefit of Chinese Patent Application No. 202311574422.5 filed on Nov. 23, 2023. All the above are hereby incorporated by reference in their entirety.

### TECHNICAL FIELD

The present disclosure relates to the field of transformer fault detection, and in particular, to a method for training a transformer fault detection model, a fault diagnosis method, and a related device.

### BACKGROUND

A transformer is one of important devices in a power system, and its normal operation is of great significance for ensuring stability and reliability of the power system. However, due to long-term operation, aging, overloading, and other reasons, the transformer is prone to various faults such as winding deformation, poor contact, and short-circuiting. These faults not only affect normal operation of the power system, but also may even cause serious safety accidents. Therefore, timely diagnosis and localization of a transformer fault are of great significance.

Traditional transformer fault diagnosis methods mainly include electrical testing, oil sample analysis, and the like. However, these methods often require a lot of time and manpower, and are difficult to accurately diagnose a fault type and location in some cases.

In view of this, how to accurately detect the transformer fault has become an important problem to be solved.

### SUMMARY

In view of this, an objective of the present disclosure is to provide a method for training a transformer fault detection model, a fault diagnosis method, and a related device, to solve or partially solve the foregoing problems.

Based on the foregoing objective, a first aspect of the present disclosure provides a method for training a transformer fault detection model, including:

obtaining an initial voiceprint signal of a transformer and a fault type corresponding to the initial voiceprint signal;

preprocessing the initial voiceprint signal by a wavelet packet analysis method to obtain an input signal, and establishing an input signal dataset based on the input signal and the fault type, where the input signal dataset includes a training dataset;

performing feature extraction on a first input signal in the training dataset based on a preset feature extraction algorithm to obtain a first voiceprint feature corresponding to the first input signal;

training an initial detection model based on the first voiceprint feature and a first fault type corresponding to the first input signal to obtain a first training result;

determining a loss function based on the first training result and the fault type; and

iteratively adjusting a weight value of the initial detection model by a backpropagation algorithm based on the loss function until the loss function converges to obtain a fault detection model, such that a to-be-detected transformer is regulated and controlled based on a fault diagnosis result obtained by performing fault detection on the to-be-detected transformer based on the fault detection model.

Based on a same inventive concept, a second aspect of the present disclosure provides a transformer fault diagnosis method, including:

obtaining an initial target voiceprint signal of a target transformer, and preprocessing the initial target voiceprint signal to obtain a target voiceprint signal; and

inputting the target voiceprint signal into a fault detection model obtained based on the method for training a transformer fault detection model, such that the fault detection model performs processing to output a fault diagnosis result corresponding to the target transformer.

Based on a same inventive concept, a third aspect of the present disclosure provides an apparatus for training a transformer fault detection model, including:

a signal obtaining module configured to obtain an initial voiceprint signal of a transformer and a fault type corresponding to the initial voiceprint signal;

a preprocessing module configured to preprocess the initial voiceprint signal by a wavelet packet analysis method to obtain an input signal, and establish an input signal dataset based on the input signal and the fault type, where the input signal dataset includes a training dataset;

a feature extraction module configured to perform feature extraction on a first input signal in the training dataset based on a preset feature extraction algorithm to obtain a first voiceprint feature corresponding to the first input signal;

a model training module configured to train an initial detection model based on the first voiceprint feature and a first fault type corresponding to the first input signal to obtain a first training result;

a loss function determining module configured to determine a loss function based on the first training result and the fault type; and

a weight adjustment module configured to iteratively adjust a weight value of the initial detection model by a backpropagation algorithm based on the loss function until the loss function converges to obtain a fault detection model, such that a to-be-detected transformer is regulated and controlled based on a fault diagnosis result obtained by performing fault detection on the to-be-detected transformer based on the fault detection model.

Based on a same inventive concept, a fourth aspect of the present disclosure provides a transformer fault diagnosis apparatus, including:

a preprocessing module configured to obtain an initial target voiceprint signal of a target transformer, and preprocess the initial target voiceprint signal to obtain a target voiceprint signal; and

a diagnosis result output module configured to input the target voiceprint signal into a fault detection model obtained based on the method for training a transformer fault detection model, such that the fault detection model performs processing to output a fault diagnosis result corresponding to the target transformer.

Based on a same inventive concept, a fifth aspect of the present disclosure provides an electronic device, including a memory, a processor, and a computer program stored in the memory and executable by the processor, where the processor executes the computer program to implement the method for training a transformer fault detection model or the transformer fault diagnosis method.

Based on a same inventive concept, a sixth aspect of the present disclosure provides a non-transitory computer-readable storage medium, storing a computer instruction, where the computer instruction is configured to enable a computer to execute the method for training a transformer fault detection model or the transformer fault diagnosis method.

From the above, it can be seen that according to the method for training a transformer fault detection model, the fault diagnosis method, and the related device provided in the present disclosure, the initial voiceprint signal of the transformer and the corresponding fault type of the initial voiceprint signal are obtained. The initial voiceprint signal is preprocessed by the wavelet packet analysis method to obtain the input signal, thereby reducing interference from environmental noise. The feature extraction is performed on the first input signal in a training dataset based on the preset feature extraction algorithm to obtain the first voiceprint feature corresponding to the first input signal, such that the first voiceprint feature is subsequently used for model training. The initial detection model is trained based on the first voiceprint feature and the first fault type corresponding to the first input signal to obtain the first training result. The loss function is determined based on the first training result and the fault type, to use the loss function to determine time when the model is completely trained. Based on the loss function, the weight value of the initial detection model is iteratively adjusted by the backpropagation algorithm based on the loss function until the loss function converges, and the fault detection model is obtained, such that a trained fault detection model is used to recognize a voiceprint signal input into the model to determine whether a transformer corresponding to the voiceprint signal fails, thereby achieving a more accurate determining result.

### BRIEF DESCRIPTION OF THE DRAWINGS

To describe the technical solutions in the present disclosure or in related technologies more clearly, the following briefly describes the accompanying drawings required for describing the embodiments or the related technologies. Apparently, the accompanying drawings in the following description show merely embodiments of the present disclosure, and a person of ordinary skill in the art may still derive other accompanying drawings from these accompanying drawings without creative efforts.

FIG. 1 is a flowchart of a method for training a transformer fault detection model according to an embodiment of the present disclosure;

FIG. 2 is a flowchart of a transformer fault diagnosis method according to an embodiment of the disclosure;

FIG. 3 is a structural block diagram of an apparatus for training a transformer fault detection model according to an embodiment of the present disclosure;

FIG. 4 is a structural block diagram of a transformer fault diagnosis apparatus according to an embodiment of the present disclosure; and

FIG. 5 is a schematic structural diagram of an electronic device according to an embodiment of the present disclosure.

### DETAILED DESCRIPTION

To make the objectives, technical solutions, and advantages of the present disclosure clearer and more comprehensible, the present disclosure is described in further detail below with reference to specific embodiments and accompanying drawings.

It should be noted that, unless otherwise defined, the technical and scientific terms used in the embodiments of the present disclosure are as they are usually understood by those skilled in the art to which the present disclosure pertains. The “first”, “second”, and similar words used in the embodiments of the present disclosure do not denote any order, quantity or importance, but are merely intended to distinguish between different constituents. “Comprising/including”, “containing”, and similar words mean that an element or article appearing before “comprising/including” or “containing” include elements or articles and their equivalent elements listed behind “comprising/including” or “containing”, not excluding any other elements or articles. Terms such as “connected to” and “connected with” are not restricted to physical or mechanical connections, but may also include direct and indirect electrical connections. “Upper”, “lower”, “left”, “right”, and the like are used only to indicate a relative positional relationship, and when an absolute position of the described object is changed, the relative positional relationship is also changed accordingly.

The terms involved in the present disclosure are explained as follows:

Digital signal processor (DSP): It is a microprocessor that has a special structure and processes a large amount of information by a digital signal.

Waveform audio file format (WAV): It is a standard digital audio file developed by Microsoft specifically for Windows.

Pulse code modulation (PCM) coding: It is one of coding methods in digital communication. A main process is to sample voice, image, and other analog signals at regular intervals, discretize the analog signals, round a sampled value to a nearest integer by hierarchical unit for quantization, and represent the sampled value by a set of binary codes to indicate an amplitude of a sampling pulse.

Analog-to-digital converter (ADC): It is a type of device configured to convert continuous analog signals into discrete digital signals.

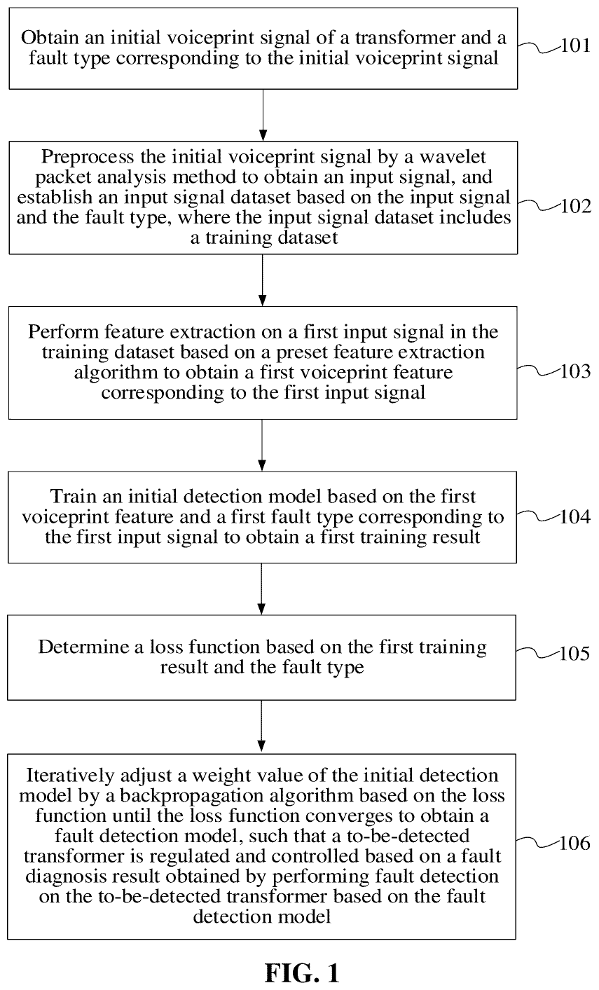

Based on the above description, an embodiment provides a method for training a transformer fault detection model. As shown in FIG. 1, the method includes the following steps:

Step 101: Obtain an initial voiceprint signal of a transformer and a fault type corresponding to the initial voiceprint signal.

During specific implementation, at least one voiceprint sensor is installed around the transformer to collect a voiceprint signal generated during operation of the transformer. The voiceprint sensor collects the voiceprint signal of the transformer at a preset sampling frequency, and collected voiceprint signals belong to a same frequency range. In this embodiment, the preset sampling frequency is 96 kHZ, and the frequency range is 0 KHz to 40 KHz.

A data format of the voiceprint signal is as follows: single audio duration of 10 seconds, an audio sampling rate of 48 kHz, sampling accuracy of 16 bits, a single channel, PCM coding, and a WAV format.

The initial voiceprint signal of the transformer and the fault type corresponding to the initial voiceprint signal are obtained. The fault type is a pre-labeled fault type of the transformer. The fault type of the transformer includes at least one of the following: a winding fault, a bushing fault, an iron core fault, a gas protection fault, a transformer fire, a tap changer fault, and the like.

Step 102: Preprocess the initial voiceprint signal by a wavelet packet analysis method to obtain an input signal, and establish an input signal dataset based on the input signal and the fault type, where the input signal dataset includes a training dataset.

During specific implementation, the obtained initial voiceprint signal is preprocessed by the wavelet packet analysis method to obtain the input signal. The preprocessing includes at least one of denoising or data enhancement. The denoising includes at least one of segmentation, framing, windowing, and adaptive filtering. The data enhancement includes at least one of cutting, noise addition, and tone tuning.

The input signal dataset is established based on the input signal obtained through the preprocessing and the fault type corresponding to the transformer. Data in the input signal dataset is randomly divided based on a preset ratio to obtain the training dataset and a test dataset.

For example, the input signal dataset contains 6000 pieces of data, the preset ratio is 5:1, the training dataset contains 5000 pieces of data, and the test dataset contains 1000 pieces of data.

Step 103: Perform feature extraction on a first input signal in the training dataset based on a preset feature extraction algorithm to obtain a first voiceprint feature corresponding to the first input signal.

During specific implementation, the feature extraction is performed on the first input signal in the training dataset by the preset feature extraction algorithm to obtain the first voiceprint feature corresponding to the first input signal. The first voiceprint feature is a feature parameter reflecting a feature of an operating status of the transformer, and the feature includes at least one of a spectral feature, a cepstral feature, and a linear predictive coding coefficient.

Step 104: Train an initial detection model based on the first voiceprint feature and a first fault type corresponding to the first input signal to obtain a first training result.

During specific implementation, the initial detection model is trained based on the obtained first voiceprint feature and the first fault type corresponding to the first input signal, and the first training result is output through the model. The first training result indicates whether the transformer corresponding to the first voiceprint feature fails.

Step 105: Determine a loss function based on the first training result and the fault type.

Step 106: Iteratively adjust a weight value of the initial detection model by a backpropagation algorithm based on the loss function until the loss function converges to obtain a fault detection model, such that a to-be-detected transformer is regulated and controlled based on a fault diagnosis result obtained by performing fault detection on the to-be-detected transformer based on the fault detection model.

During specific implementation, the loss function is determined based on the output first training result and the fault type, and the weight value of the initial detection model is updated by the backpropagation algorithm. Iterative training is performed until the loss function converges, and the training ends to obtain the fault detection model.

The backpropagation algorithm is a method of modifying a labeled model at each layer. Starting from a labeled result at a high layer, based on a dependency relationship between a labeled feature and a feature function, the method corrects a weight of a feature function that the labeled result depends on and is less than a preset threshold. Through a hierarchical progressive relationship, a weight of a feature function with low credibility at each layer is reduced.

The weight value of the initial detection model is updated by the backpropagation algorithm, which is expressed as a following formula:

$$delta\_weights = - alpha * ( gradient * weights ) + regularization * weights$$

In the above formula, alpha represents a learning rate, gradient represents a gradient, and weights represent weights of a network.

Through machine learning and deep learning algorithms, different voiceprint features can be more accurately recognized and distinguished, thereby achieving higher discriminability for voiceprint features of different faults, reducing a possibility of misrecognition. Meanwhile, a voiceprint recognition technology based on artificial intelligence has strong robustness and can automatically adapt to various types of environmental noise and other interference factors, thereby reducing their impacts on recognition accuracy.

According to the above solution, the initial voiceprint signal of the transformer and the fault type corresponding to the initial voiceprint signal are obtained. The initial voiceprint signal is preprocessed by the wavelet packet analysis method to obtain the input signal, thereby reducing interference from environmental noise. The feature extraction is performed on the first input signal in the training dataset based on the preset feature extraction algorithm to obtain the first voiceprint feature corresponding to the first input signal, such that the first voiceprint feature is subsequently used for model training. The initial detection model is trained based on the first voiceprint feature and the first fault type corresponding to the first input signal to obtain the first training result. The loss function is determined based on the first training result and the fault type, to use the loss function to determine a time when the model is completely trained. Based on the loss function, the weight value of the initial detection model is iteratively adjusted by the backpropagation algorithm based on the loss function until the loss function converges, and the fault detection model is obtained, such that a trained fault detection model is used to recognize a voiceprint signal input into the model to determine whether a transformer corresponding to the voiceprint signal fails, thereby achieving a more accurate determining result.

In detail, the fault diagnosis result obtained by the fault detection model by performing the fault detection on the to-be-detected transformer includes a fault such as direct current magnetic biasing, partial discharge, transmission jamming, internal looseness, overloading, overexcitation, or winding deformation. Based on the fault diagnosis result obtained by the fault detection model by performing the fault detection on the to-be-detected transformer, an output voltage of the to-be-detected transformer and/or on/off of a relay are/is correspondingly regulated and controlled, and the fault existing in the to-be-detected transformer is repaired to ensure normal operation of the transformer.

In some embodiments, the step 102 specifically includes the following sub-steps:

Step 1021: Perform digital processing on the initial voiceprint signal to obtain an initial digital signal.

During specific implementation, after the initial voiceprint signal is obtained, a digital signal processor is first used to perform the digital processing on the initial voiceprint signal to convert the initial voiceprint signal into the initial digital signal. The initial digital signal is signal data that can be recognized by a computer.

Step 1022: Denoise the initial digital signal by the wavelet packet analysis method to obtain a standard digital signal.

During specific implementation, the initial digital signal is denoised by the wavelet packet analysis method to obtain a clean digital signal, and noise interference is removed from the initial digital signal.

In some embodiments, a missing value is filled in the clean digital signal to obtain the standard digital signal. The missing value is filled by an interpolation method. The interpolation method is a method of fitting a curve or polynomial based on a known data point, and then using the curve or polynomial to estimate a value of an unknown point.

In this embodiment, linear interpolation is used to fill the missing value, which is expressed as a following formula:

$$y = y 1 + ( x - x 1 ) * ( y 2 - y 1 ) / ( x 2 - x 1 )$$

In the above formula, (x1, y1) and (x2, y2) represent known adjacent data points, and (x, y) represents an unknown point that needs to be estimated.

Step 1023: Normalize the standard digital signal to obtain the input signal.

During specific implementation, the obtained standard digital signal is normalized to obtain the input signal. In this embodiment, a min-max normalization method is adopted for the normalization. The min-max normalization method is a normalization method that maps data to a range of [0, 1]. The min-max normalization method is expressed as a following formula:

$$y = ( x - min ) / ( max - min )$$

In the above formula, x represents original data, and max and min respectively represent maximum and minimum values in the data. After the min-max normalization, the data is mapped to the range of [0, 1].

In some embodiments, the step 1022 specifically includes the following sub-steps:

Step 10221: Decompose the initial digital signal based on a preset scale to obtain a plurality of initial digital sub-signals.

During specific implementation, the initial digital signal is decomposed based on the preset scale. In this embodiment, the preset scale is preferably 3, and the wavelet packet analysis method is expressed as a following formula:

$$y ( n ) = x ( n ) + d ( n ) ;$$

In the above formula, y(n) represents the initial digital signal. It is set that y(n)=a₀(k), and a Daubechies wavelet is taken for a mother wavelet function. Multi-scale decomposition is performed on the a₀(K) to obtain a plurality of initial digital sub-signals, where the initial digital sub-signals are signals at different frequencies. After wavelet transform, the initial digital signal a₀(k) is decomposed into:

$${a}_{0} ( k ) = {\sum }_{i = 1}^{N} {a}_{i} ( k ) + {d}_{N} ( k ) ;$$

In the above formula, N=3, and d_{N}(k) has a same meaning as the d(n) mentioned above.

Step 10222: Perform spectral subtraction on each initial digital sub-signal based on a preset window width to obtain a digital sub-signal.

During specific implementation, each initial digital sub-signal is treated as an independent signal for the spectral subtraction. When the spectral subtraction is performed, the preset window width is used. In this embodiment, window lengths of the a₂(k), the a₁(k), the a₃(k), and the d₃(k) are respectively 64, 128, 256, and 512, and window shapes are Hamming windows.

Step 10223: Perform an addition operation on all the obtained digital sub-signals to obtain the standard digital signal.

During specific implementation, all the obtained digital sub-signals are combined and added up to obtain the standard digital signal.

In some embodiments, the step 103 specifically includes the following sub-steps:

Step 1031: For each first input signal in the training dataset, perform the feature extraction on the first input signal based on the preset feature extraction algorithm to obtain a time-domain feature and frequency-domain feature corresponding to the first input signal.

During specific implementation, for each first input signal in the training dataset, time-domain feature extraction and frequency-domain feature extraction are separately performed by the preset feature extraction algorithm. The time-domain feature extraction uses a preset algorithm to analyze the first input signal to obtain a voiceprint feature that reflects the operating status of the transformer. The voiceprint feature is the time-domain feature. The frequency-domain feature extraction is to perform spectral analysis on the first input signal to extract a spectral parameter that reflects the feature of the operating status of the transformer.

Step 1032: Perform weighted calculation on the time-domain feature and the frequency-domain feature to obtain the first voiceprint feature corresponding to the first input signal.

During specific implementation, the weighted calculation is performed on the time-domain feature and the frequency-domain feature based on a preset weight value to obtain the first voiceprint feature corresponding to the first input signal. For example, a weight value corresponding to the time-domain feature is 0.8, and a weight value corresponding to the frequency-domain feature is 0.2.

In some embodiments, the step 1031 specifically includes the following sub-steps:

Step 10311: Calculate an energy value of the first input signal by an energy detection algorithm.

Step 10312: Obtain a signal length and a signal amplitude of the first input signal, determine duration of the first input signal based on the signal length, and determine an amplitude of the first input signal based on the signal amplitude.

During specific implementation, the energy value of the first input signal is calculated by the energy detection algorithm. Code for the energy detection algorithm is as follows:

$$energy = sum ( abs ( signal ) \hat{} 2 )$$

In the above formula, energy represents the energy value, and signal represents the first input signal.

The signal amplitude and the signal length of the first input signal are obtained, and the amplitude corresponding to the first input signal is calculated based on the signal amplitude. Code for an amplitude calculation method is as follows:

$$amplitude\_distribution = histogram ( abs ( signal ) )$$

In the above formula, amplitude_distribution represents the amplitude.

The duration of the first input signal is calculated based on the obtained signal length of the first input signal. Code for the duration is as follows:

$$duration = length ( signal )$$

In the above formula, duration represents the duration.

Step 10313: Input the energy value, the duration, and the amplitude of the first input signal into the preset feature extraction algorithm to obtain the time-domain feature of the first input signal.

During specific implementation, the calculated energy value, duration, and amplitude of the first input signal are input into the preset feature extraction algorithm, and the feature extraction algorithm outputs the corresponding time-domain feature of the first input signal. The preset feature extraction algorithm may be a pre-trained algorithm that obtains the time-domain feature of the first input signal based on the energy value, the duration, and the amplitude of the first input signal.

Step 10314: Perform Fourier transform on the first input signal to obtain a corresponding spectrum of the first input signal.

During specific implementation, the first input signal is a time-domain signal, and the first input signal is converted from the time-domain signal to a frequency-domain signal. In this embodiment, the Fourier transform is performed to obtain the corresponding spectrum of the first input signal.

Step 10315: Obtain maximum and minimum values in the corresponding spectrum of the first input signal, and input the maximum and minimum values into the preset feature extraction algorithm to obtain the frequency-domain feature of the first input signal.

During specific implementation, peak value extraction and valley value extraction are performed on the corresponding spectrum of the first input signal, that is, the maximum and minimum values in the corresponding spectrum of the first input signal are obtained. The maximum and minimum values are input into the preset feature extraction algorithm to output the corresponding frequency-domain feature of the first input signal. The preset feature extraction algorithm may be a pre-trained algorithm that obtains the frequency-domain feature of the first input signal based on maximum and minimum values of the first input signal.

In some embodiments, the input signal dataset further includes the test dataset, and the method further includes the following steps:

Step A: Perform the feature extraction on a second input signal in the test dataset to obtain a second voiceprint feature.

During specific implementation, second input data in the test dataset is obtained, and the feature extraction is performed on the second input data to obtain the second voiceprint feature.

A method for extracting the second voiceprint feature includes:

calculating an energy value of the second input signal by the energy detection algorithm, obtaining a signal length and a signal amplitude of the second input signal, determining duration of the second input signal based on the signal length, and determining an amplitude of the second input signal based on the signal amplitude; inputting the energy value, the duration, and the amplitude of the second input signal into the preset feature extraction algorithm to obtain a time-domain feature of the second input signal;

performing the Fourier transform on the second input signal to obtain a corresponding spectrum of the second input signal; obtaining maximum and minimum values in the corresponding spectrum of the second input signal, and inputting the maximum and minimum values into the preset feature extraction algorithm to obtain a frequency-domain feature of the second input signal; and

performing the weighted calculation on the time-domain feature and the frequency-domain feature to obtain the corresponding second voiceprint feature of the second input signal.

Step B: Input the second voiceprint feature into the fault detection model to obtain a second training result.

Step C: Compare the second training result with a fault type corresponding to the second voiceprint feature, and output a comparison result, where the comparison result is used to indicate whether the second training result is the same as the fault type corresponding to the second voiceprint feature.

During specific implementation, the second voiceprint feature is input into the fault detection model, such that the fault detection model performs processing to obtain the second training result.

If a transformer corresponding to the second voiceprint feature fails, a fault type of the transformer corresponding to the second voiceprint feature is obtained, whether the second training result indicates that the transformer fails is determined, and a fault type corresponding to the second training result is compared with the fault type corresponding to the second voiceprint feature to determine whether the second training result is the same as the fault type, thereby determining accuracy of the model.

In some embodiments, the transformer corresponding to the second voiceprint feature may not fail. Therefore, after the second training result is obtained, whether the second training result indicates that the transformer does not fail is determined to determine the accuracy of the model.

Based on the test dataset, statistics are performed on the accuracy, a false detection rate, a missed detection rate, and average calculation time that correspond to the fault detection model. Performance of the fault detection model is determined based on these four indicators to determine whether the fault detection model can be put into use in the future.

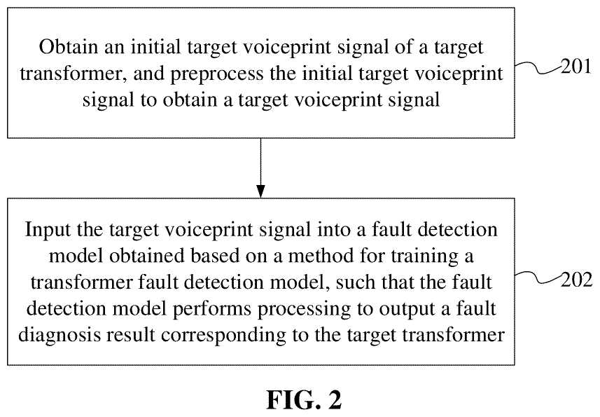

Another embodiment of the present disclosure provides a transformer fault diagnosis method, which applies the fault detection model obtained in the above embodiments. As shown in FIG. 2, the method includes the following steps:

Step 201: Obtain an initial target voiceprint signal of a target transformer, and preprocess the initial target voiceprint signal to obtain a target voiceprint signal.

During specific implementation, the initial target voiceprint signal of the target transformer is obtained, and the target transformer is a to-be-detected transformer. The initial target voiceprint signal is preprocessed to obtain the target voiceprint signal.

A specific process of preprocessing the initial target voiceprint signal includes:

performing digital processing on the initial target voiceprint signal to obtain an initial target digital signal, and decomposing the initial digital signal based on a preset scale to obtain a plurality of initial target digital sub-signals; and

performing spectral subtraction on each initial target digital sub-signal based on a preset window width to obtain a target digital sub-signal; performing an addition operation on all the obtained target digital sub-signals to obtain a standard target digital signal; and normalizing the standard target digital signal to obtain the target voiceprint signal.

Step 202: Input the target voiceprint signal into a fault detection model obtained based on a method for training a transformer fault detection model, such that the fault detection model performs processing to output a fault diagnosis result corresponding to the target transformer.

During specific implementation, the fault detection model trained based on the above embodiments is obtained, and the target voiceprint signal is input into the fault detection model, such that the fault detection model performs the processing to output the fault diagnosis result. The fault diagnosis result indicates whether the target transformer fails, and a corresponding fault type if the target transformer fails.

According to the above solution, the trained fault detection model is used to recognize and analyze collected voiceprint information of the target transformer to determine whether the target transformer fails, which makes the determining more convenient and improves accuracy of the determining. If it is determined that the target transformer fails, the fault type of the target transformer is output in the fault diagnosis result for a user to have a preliminary understanding of the fault of the transformer and take a corresponding measure.

It should be noted that the method in this embodiment of the present disclosure may be executed by a single device, such as a computer or a server. The method in this embodiment may also be applied to a distributed scenario, and is completed through cooperation by a plurality of devices. In this distributed scenario, one of the devices may only perform one or more steps of the method described in this disclosure, and the devices interact with each other to complete the method.

It should be noted that some embodiments of the present disclosure are described above. Other embodiments fall within the scope of the appended claims. In some cases, the actions or steps described in the claims may be performed in sequences different from those in the embodiments and still achieve expected results. In addition, the processes depicted in the accompanying drawings do not necessarily require the specific orders or sequential orders shown for achieving the expected results. In some implementations, multitasking and parallel processing are also possible or may be advantageous.

Based on a same inventive concept, corresponding to the method in any of the above embodiments, the present disclosure further provides an apparatus for training a transformer fault detection model.

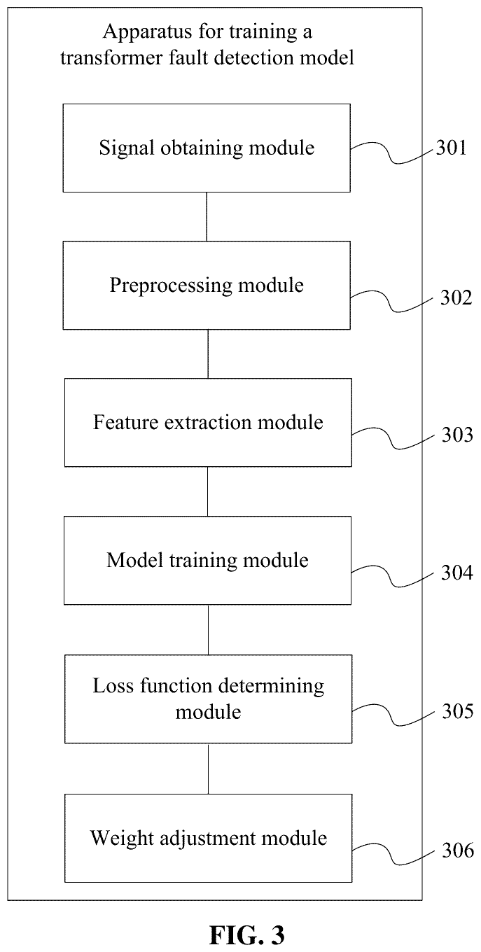

FIG. 3 shows an apparatus for training a transformer fault detection model according to an embodiment. As shown in FIG. 3, the apparatus includes:

a signal obtaining module 301 configured to obtain an initial voiceprint signal of a transformer and a fault type corresponding to the initial voiceprint signal;

a preprocessing module 302 configured to preprocess the initial voiceprint signal by a wavelet packet analysis method to obtain an input signal, and establish an input signal dataset based on the input signal and the fault type, where the input signal dataset includes a training dataset;

a feature extraction module 303 configured to perform feature extraction on a first input signal in the training dataset based on a preset feature extraction algorithm to obtain a first voiceprint feature corresponding to the first input signal;

a model training module 304 configured to train an initial detection model based on the first voiceprint feature and a first fault type corresponding to the first input signal to obtain a first training result;

a loss function determining module 305 configured to determine a loss function based on the first training result and the fault type; and

a weight adjustment module 306 configured to iteratively adjust a weight value of the initial detection model by a backpropagation algorithm based on the loss function until the loss function converges, and obtain a fault detection model.

In some embodiments, the preprocessing module 302 specifically includes:

a digital processing unit configured to perform digital processing on the initial voiceprint signal to obtain an initial digital signal;

a denoising unit configured to denoise the initial digital signal by the wavelet packet analysis method to obtain a standard digital signal; and

a normalization unit configured to normalize the standard digital signal to obtain the input signal.

In some embodiments, the denoising unit specifically includes:

a signal decomposition subunit configured to decompose the initial digital signal based on a preset scale to obtain a plurality of initial digital sub-signals;

a spectral subtraction subunit configured to perform spectral subtraction on each initial digital sub-signal based on a preset window width to obtain a digital sub-signal; and

an addition subunit configured to perform an addition operation on all the obtained digital sub-signals to obtain the standard digital signal.

In some embodiments, the feature extraction module 303 specifically includes:

a feature extraction unit configured to: for each first input signal in the training dataset, perform the feature extraction on the first input signal based on the preset feature extraction algorithm to obtain a time-domain feature and frequency-domain feature corresponding to the first input signal;

a weighted calculation unit configured to perform weighted calculation on the time-domain feature and the frequency-domain feature to obtain the first voiceprint feature corresponding to the first input signal.

In some embodiments, the feature extraction unit specifically includes:

an energy value calculation subunit configured to calculate an energy value of the first input signal by an energy detection algorithm;

an amplitude calculation subunit configured to obtain a signal length and a signal amplitude of the first input signal, determine duration of the first input signal based on the signal length, and determine an amplitude of the first input signal based on the signal amplitude;

a time-domain feature extraction subunit configured to input the energy value, the duration, and the amplitude of the first input signal into the preset feature extraction algorithm to obtain the time-domain feature of the first input signal;

a spectrum determining subunit configured to perform Fourier transform on the first input signal to obtain a spectrum corresponding to the first input signal; and

a frequency-domain feature extraction subunit configured to obtain maximum and minimum values in the spectrum corresponding to the first input signal, and input the maximum and minimum values into the preset feature extraction algorithm to obtain the frequency-domain feature of the first input signal.

In some embodiments, the apparatus further includes a test module, and the test module includes:

a feature extraction unit configured to perform the feature extraction on a second input signal in the test dataset to obtain a second voiceprint feature;

a training result generation unit configured to input the second voiceprint feature into the fault detection model to obtain a second training result; and

a result comparison unit configured to compare the second training result with a fault type corresponding to the second voiceprint feature, and output a comparison result, where the comparison result is used to indicate whether the second training result is the same as the fault type corresponding to the second voiceprint feature.

Based on a same inventive concept, corresponding to the method in any of the above embodiments, the present disclosure further provides a transformer fault diagnosis apparatus.

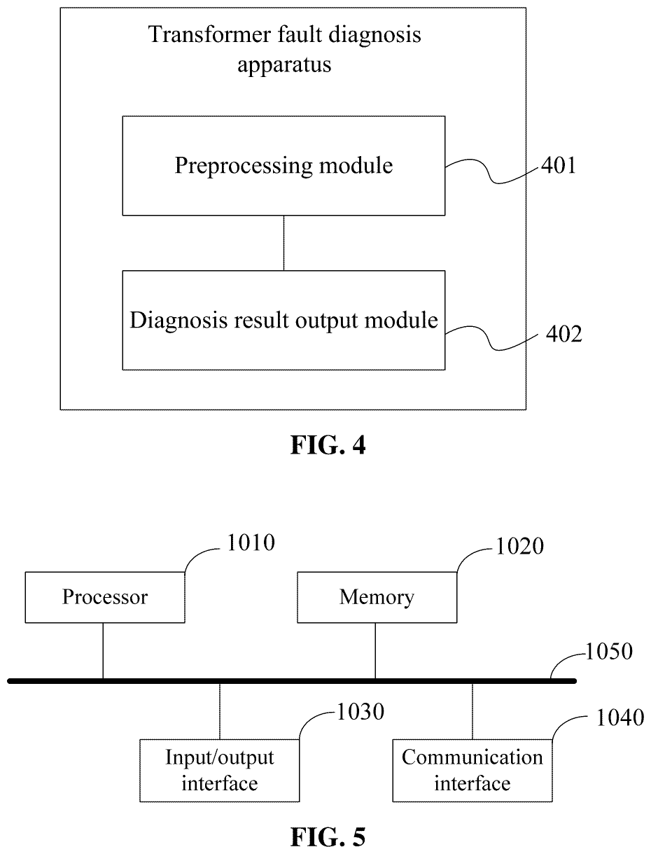

FIG. 4 shows a transformer fault diagnosis apparatus according to an embodiment. As shown in FIG. 4, the transformer fault diagnosis apparatus includes:

a signal obtaining module 401 configured to obtain an initial target voiceprint signal of a target transformer, and preprocess the initial target voiceprint signal to obtain a target voiceprint signal; and

a result output module 402 configured to input the target voiceprint signal to a fault detection model, such that the fault detection model performs processing to output a fault diagnosis result corresponding to the target transformer, so as to regulate and control a to-be-detected transformer based on a fault diagnosis result obtained by performing fault detection on the to-be-detected transformer based on the fault detection model.

In another implementation example, the apparatus for training a transformer fault detection model includes a processor. The processor is configured to execute the above program modules stored in a memory, including the signal obtaining module 301, the preprocessing module 302, the feature extraction module 303, the model training module 304, the loss function determining module 305, the weight adjustment module 306, the signal obtaining module 401, and the result output module 402.

For ease of description, the foregoing apparatuses are divided into various modules based on functions for separate description. Certainly, the functions of the modules may be implemented in one or more pieces of software and/or hardware during implementation of the present disclosure.

The apparatus in the above embodiment is configured to implement the corresponding method for training a transformer fault detection model in any one of the above embodiments, and has beneficial effects of the corresponding method embodiment. Details are not described herein again.

Based on a same inventive concept, corresponding to the method in any of the above embodiments, the present disclosure further provides an electronic device, including a memory, a processor, and a computer program stored in the memory and executable on the processor. The processor executes the computer program to implement the method for training a transformer fault detection model in any one of the above embodiments.

FIG. 5 is a more specific schematic diagram of a hardware structure of an electronic device according to an embodiment. The device may include a processor 1010, a memory 1020, an input/output interface 1030, a communication interface 1040, and a bus 1050. The processor 1010, the memory 1020, the input/output interface 1030, and the communication interface 1040 are communicatively connected in the device through the bus 1050.

The processor 1010 may be implemented by a general central processing unit (CPU), a microprocessor, an application specific integrated circuit (ASIC), or one or more integrated circuits, and is configured to execute related programs to implement the technical solutions provided in the embodiments of the present disclosure.

The memory 1020 may be implemented in a form of a read-only memory (ROM), a random access memory (RAM), a static storage device, a dynamic storage device, or the like. The memory 1020 may store an operating system and other application programs. When the technical solutions provided in the embodiments of the present disclosure are implemented by software or firmware, related program code is stored in the memory 1020 and called and executed by the processor 1010.

The input/output interface 1030 is configured to connect an input/output module to input and output information. The input/output module may be configured in the device as a component (not shown in the figure), or may be externally connected to the device to provide a corresponding function. Input devices may include a keyboard, a mouse, a touch screen, a microphone, various sensors, and the like. Output devices may include a display, a speaker, a vibrator, an indicator light, and the like.

The communication interface 1040 is configured to connect a communication module (not shown in the figure) to implement communication and interaction between the device and other devices. The communication module may implement communication in a wired manner (such as a USB or a network cable) or in a wireless manner (such as a mobile network, Wi-Fi, or Bluetooth).

The bus 1050 includes a path for transmitting information between various components (such as the processor 1010, the memory 1020, the input/output interface 1030, and the communication interface 1040) of the device.

It should be noted that although only the processor 1010, the memory 1020, the input/output interface 1030, the communication interface 1040, and the bus 1050 are shown for the device, in a specific implementation process, the device may further include other components required for normal operation. In addition, those skilled in the art may understand that the device may include only components required for implementing the solutions in the embodiments of the present disclosure, and not necessarily include all the components shown in the figure.

The electronic device in the above embodiment is configured to implement the corresponding method for training a transformer fault detection model in any one of the above embodiments, and has beneficial effects of the corresponding method embodiment. Details are not described herein again.

Based on a same inventive concept, corresponding to the method in any of the above embodiments, the present disclosure provides a non-transitory computer-readable storage medium, storing a computer instruction. The computer instruction is configured to enable a computer to execute the method for training a transformer fault detection model described in any one of the above embodiments.

The computer-readable medium in this embodiment includes persistent, non-persistent, removable, and non-removable media, and storage of information may be implemented by any method or technology. The information may be a computer-readable instruction, a data structure, a program module, or other data. Examples of a computer storage medium include, but are not limited to, a phase-change random access memory (PRAM), a static random access memory (SRAM), a dynamic random access memory (DRAM), other types of RAMs, a ROM, an electrically erasable programmable read-only memory (EEPROM), a flash memory or another memory technology, a compact disc ROM (CD-ROM), a digital versatile disk (DVD) or another optical storage device, a magnetic cassette tape, and a magnetic tape disk storage device or another magnetic storage device or any other non-transmission medium that can be configured to store information that can be accessed by a computing device.

The computer instruction stored in the storage medium in the above embodiment is configured to enable a computer to execute the method for training a transformer fault detection model in any one of the above embodiments, and has beneficial effects of the corresponding method embodiment. Details are not described herein again.

It can be understood that before using the technical solutions in the embodiments of the present disclosure, a user is informed of a type, a usage scope, and a usage scenario of involved personal information in an appropriate manner, and authorization is obtained from the user.

For example, in response to receiving an active request from the user, a prompt message is sent to the user to clearly prompt the user that the personal information of the user needs to be obtained and used for a requested operation. Therefore, based on the prompt message, the user can autonomously choose whether to provide the personal information to software or hardware such as an electronic device, an application program, a server, or a storage medium that performs operations of the technical solutions in the present disclosure.

As an optional but non-limiting implementation, in response to receiving the active request from the user, for example, the prompt message may be sent to the user by means of a pop-up window. The prompt message can be presented in a text format in the pop-up window. In addition, the pop-up window can also carry a selection control for the user to choose whether to “agree” or “disagree” to provide the personal information to the electronic device.

It can be understood that the above user authorization notification and obtaining process is only illustrative and does not limit the implementations in the present disclosure. Other methods that comply with relevant laws and regulations can also be applied to the implementations in the present disclosure.

Those of ordinary skill in the art should understand that the discussion of any of the above embodiments is only exemplary, and is not intended to imply that the scope of the present disclosure (including the claims) is limited to these examples. Under the idea of the present disclosure, the above embodiments or the technical features in different embodiments can also be combined, the steps can be implemented in any order, and many other changes in different aspects of the embodiments in the present disclosure are included, which are not provided in the details for brevity.

In addition, to simplify the description and discussion without making the embodiments of the present disclosure difficult to understand, the well-known power/ground connections to an integrated circuit (IC) chip and other components may or may not be shown in the accompanying drawings. In addition, the apparatuses may be shown in a form of block diagrams to make it easy to understand the embodiments of the present disclosure. In addition, the details about the implementations of the apparatuses in the block diagrams are highly dependent on the platform on which the embodiments of the present disclosure will be implemented (that is, these details should be fully understandable to those skilled in the art). When specific details (for example, a circuit) are provided to describe the exemplary embodiments of the present disclosure, it is obvious that those skilled in the art can implement the embodiments of the present disclosure without these specific details or in case of any changes to these specific details. Therefore, these descriptions should be considered illustrative rather than restrictive.

Although the present disclosure has been described with reference to the specific embodiments of the present disclosure, many substitutions, modifications, and variations of these embodiments will be obvious to those of ordinary skill in the art based on the foregoing description. For example, other memory architectures (for example, a DRAM) can be used in the discussed embodiments.

The embodiments of the present disclosure are intended to cover all such substitutions, modifications, and variations that fall within the broad scope of the appended claims. Therefore, any omissions, modifications, equivalent substitutions, improvements, and the like made within the spirit and scope of the embodiments in the present disclosure should fall within the protection scope of the present disclosure.

1. A method for training a transformer fault detection model, comprising:
obtaining an initial voiceprint signal of a transformer and a fault type corresponding to the initial voiceprint signal;
preprocessing the initial voiceprint signal by a wavelet packet analysis method to obtain an input signal, and establishing an input signal dataset based on the input signal and the fault type, wherein the input signal dataset comprises a training dataset;
performing feature extraction on a first input signal in the training dataset based on a preset feature extraction algorithm to obtain a first voiceprint feature corresponding to the first input signal;
training an initial detection model based on the first voiceprint feature and a first fault type corresponding to the first input signal to obtain a first training result;
determining a loss function based on the first training result and the first fault type; and
iteratively adjusting a weight value of the initial detection model by a backpropagation algorithm based on the loss function until the loss function converges to obtain a fault detection model, whereby a to-be-detected transformer is regulated and controlled based on a fault diagnosis result obtained by performing fault detection on the to-be-detected transformer based on the fault detection model.

2. The method according to claim 1, wherein the preprocessing the initial voiceprint signal by a wavelet packet analysis method to obtain an input signal comprises:
performing digital processing on the initial voiceprint signal to obtain an initial digital signal;
denoising the initial digital signal by the wavelet packet analysis method to obtain a standard digital signal; and
normalizing the standard digital signal to obtain the input signal.

3. The method according to claim 2, wherein the denoising the initial digital signal by the wavelet packet analysis method to obtain a standard digital signal comprises:
decomposing the initial digital signal based on a preset scale to obtain a plurality of initial digital sub-signals;
performing spectral subtraction on each initial digital sub-signal based on a preset window width to obtain a digital sub-signal; and
performing an addition operation on all the obtained digital sub-signals to obtain the standard digital signal.

4. The method according to claim 1, wherein the performing feature extraction on a first input signal in the training dataset based on a preset feature extraction algorithm to obtain a first voiceprint feature corresponding to the first input signal comprises:
for each first input signal in the training dataset:
performing the feature extraction on the first input signal based on the preset feature extraction algorithm to obtain a time-domain feature and a frequency-domain feature corresponding to the first input signal; and
performing weighted calculation on the time-domain feature and the frequency-domain feature to obtain the first voiceprint feature corresponding to the first input signal.

5. The method according to claim 4, wherein the performing the feature extraction on the first input signal based on the preset feature extraction algorithm to obtain a time-domain feature and a frequency-domain feature corresponding to the first input signal comprises:
calculating an energy value of the first input signal by an energy detection algorithm;
obtaining a signal length and a signal amplitude of the first input signal, determining duration of the first input signal based on the signal length, and determining an amplitude of the first input signal based on the signal amplitude;
inputting the energy value, the duration, and the amplitude of the first input signal into the preset feature extraction algorithm to obtain the time-domain feature of the first input signal;
performing Fourier transform on the first input signal to obtain a spectrum corresponding to the first input signal; and
obtaining maximum and minimum values in the spectrum corresponding to the first input signal, and inputting the maximum and minimum values into the preset feature extraction algorithm to obtain the frequency-domain feature of the first input signal.

6. The method according to claim 1, wherein the input signal dataset further comprises a test dataset; and
the method further comprises:
performing the feature extraction on a second input signal in the test dataset to obtain a second voiceprint feature;
inputting the second voiceprint feature into the fault detection model to obtain a second training result; and
comparing the second training result with a fault type corresponding to the second voiceprint feature, and outputting a comparison result, wherein the comparison result is used to indicate whether the second training result is the same as the fault type corresponding to the second voiceprint feature.

7. A transformer fault diagnosis method, comprising:
obtaining an initial target voiceprint signal of a target transformer, and preprocessing the initial target voiceprint signal to obtain a target voiceprint signal; and
inputting the target voiceprint signal into a fault detection model obtained based on the method for training a transformer fault detection model according to claim 1, whereby the fault detection model performs processing to output a fault diagnosis result corresponding to the target transformer.

8. A transformer fault diagnosis method, comprising:
obtaining an initial target voiceprint signal of a target transformer, and preprocessing the initial target voiceprint signal to obtain a target voiceprint signal; and
inputting the target voiceprint signal into a fault detection model obtained based on the method for training a transformer fault detection model according to claim 2, whereby the fault detection model performs processing to output a fault diagnosis result corresponding to the target transformer.

9. A transformer fault diagnosis method, comprising:
obtaining an initial target voiceprint signal of a target transformer, and preprocessing the initial target voiceprint signal to obtain a target voiceprint signal; and
inputting the target voiceprint signal into a fault detection model obtained based on the method for training a transformer fault detection model according to claim 3, whereby the fault detection model performs processing to output a fault diagnosis result corresponding to the target transformer.

10. A transformer fault diagnosis method, comprising:
obtaining an initial target voiceprint signal of a target transformer, and preprocessing the initial target voiceprint signal to obtain a target voiceprint signal; and
inputting the target voiceprint signal into a fault detection model obtained based on the method for training a transformer fault detection model according to claim 4, whereby the fault detection model performs processing to output a fault diagnosis result corresponding to the target transformer.

11. A transformer fault diagnosis method, comprising:
obtaining an initial target voiceprint signal of a target transformer, and preprocessing the initial target voiceprint signal to obtain a target voiceprint signal; and
inputting the target voiceprint signal into a fault detection model obtained based on the method for training a transformer fault detection model according to claim 5, whereby the fault detection model performs processing to output a fault diagnosis result corresponding to the target transformer.

12. A transformer fault diagnosis method, comprising:
obtaining an initial target voiceprint signal of a target transformer, and preprocessing the initial target voiceprint signal to obtain a target voiceprint signal; and
inputting the target voiceprint signal into a fault detection model obtained based on the method for training a transformer fault detection model according to claim 6, whereby the fault detection model performs processing to output a fault diagnosis result corresponding to the target transformer.

13. An apparatus for training a transformer fault detection model, comprising:
a signal obtaining module configured to obtain an initial voiceprint signal of a transformer and a fault type corresponding to the initial voiceprint signal;
a preprocessing module configured to preprocess the initial voiceprint signal by a wavelet packet analysis method to obtain an input signal, and establish an input signal dataset based on the input signal and the fault type, wherein the input signal dataset comprises a training dataset;
a feature extraction module configured to perform feature extraction on a first input signal in the training dataset based on a preset feature extraction algorithm to obtain a first voiceprint feature corresponding to the first input signal;
a model training module configured to train an initial detection model based on the first voiceprint feature and a first fault type corresponding to the first input signal to obtain a first training result;
a loss function determining module configured to determine a loss function based on the first training result and the fault type; and
a weight adjustment module configured to iteratively adjust a weight value of the initial detection model by a backpropagation algorithm based on the loss function until the loss function converges to obtain a fault detection model, whereby a to-be-detected transformer is regulated and controlled based on a fault diagnosis result obtained by performing fault detection on the to-be-detected transformer based on the fault detection model.

14. An electronic device, comprising a memory, a processor, and a computer program stored in the memory and operable on the processor, wherein the processor executes the program to implement the method for training a transformer fault detection model according to claim 1.

15. An electronic device, comprising a memory, a processor, and a computer program stored in the memory and operable on the processor, wherein the processor executes the program to implement the transformer fault diagnosis method according to claim 7.

16. A non-transitory computer-readable storage medium, storing a computer instruction, wherein the computer instruction is configured to enable a computer to execute the method for training a transformer fault detection model according to claim 1.

17. A non-transitory computer-readable storage medium, storing a computer instruction. wherein the computer instruction is configured to enable a computer to execute the transformer fault diagnosis method according to claim 7.
